(19) United States
(12) Patent Application Publication
(10) Pub. No.: US 2023/0395968 A1
(43) Pub. Date: Dec. 7, 2023

(54) A MULTI-LAYERED STRUCTURE HAVING ANTIPAD FORMATIONS

(71) Applicant: Metawave Corporation, Carlsbad, CA (US)

(72) Inventors: Hamidreza Kazemi, Irvine, CA (US); Soren Shams, Carlsbad, CA (US)

(21) Appl. No.: 18/249,941

(22) PCT Filed: Oct. 21, 2021
(86) PCT No.: PCT/US2021/056075

§ 371 Date: Apr. 20, 2023

Related U.S. Application Data
(60) Provisional application No. 63/104,369, filed on Oct. 22, 2020.

(51) Int. Cl. H01Q 1/22; H01L 23/498; H01L 23/66

(52) U.S. Cl. CPC H01Q 1/2283; H01L 23/49838; H01L 23/49827; H01L 23/49816; H01L 23/49822; H01L 23/66; H01L 2223/6622; H01L 2224/16225; H01L 24/16

(57) ABSTRACT

In accordance with various embodiments, a multi-layer electromagnetic device is provided. The device includes a first connectivity layer that includes a first conductive pad having a first capacitance, a feed line coupled between the first conductive pad and a transmit signal source, and a first antipad surrounding at least a portion of the first conductive pad that enables an isolation of electromagnetic signals propagating through the first conductive pad. The first antipad has a resonance that is a function of the first capacitance. The device also includes a second connectivity layer that includes a second conductive pad that enables an electrical connectivity to an external device and a plurality of layers positioned between the first connectivity layer and the second connectivity layer. The conductive pads have antipad extensions into available area of the layer as a function of a capacitance of the conductive pads.

### CROSS-REFERENCE TO RELATED APPLICATIONS

This application claims priority from U.S. Provisional Application No. 63/104,369, filed on Oct. 22, 2020, which is incorporated by reference in its entirety.

### BACKGROUND

In multi-layer semiconductor devices transmission lines are routed through and between layers forming complex mappings. The specific mapping may result in unwanted interactions between transmission lines and layers. As these mappings reduce in scale, these effects impact operation of a device. Therefore, there is a need for an improved method and/or apparatus configuration that is capable of resolving the current challenges in fabrication of devices with reduced dimensions.

### BRIEF DESCRIPTION OF THE DRAWINGS

The present application may be more fully appreciated in connection with the following detailed description taken in conjunction with the accompanying drawings, which are not drawn to scale, in which like reference characters refer to like parts throughout, and in which:

FIG. 1 illustrates an example configuration of an integrated circuity having a plurality of elements in a top view and a perspective view;

FIG. 2 illustrates a process of building a Ball Grid Array (BGA) structure by soldering or connecting directly between a chip carrier package and an interconnect substrate, in accordance with various embodiments;

FIGS. 3A, 3B, and 3C illustrate an example multi-layer device incorporating antipad formations, in accordance with various embodiments;

FIGS. 4A, 4B, 4C, and 4D illustrate layers of an example multi-layer device with antipad and conductive portions, in accordance with various embodiments;

FIGS. 5A, 5B, 5C, 5D, and 5E illustrate individual layers of an example multi-layer device with specific antipad and conductive portions, in accordance with various embodiments;

FIGS. 6A, 6B, 6C, 6D, and 6E illustrate individual layers of an example multi-layer device in an example configuration with specific antipad and conductive portions, in accordance with various embodiments;

FIGS. 7 and 8 illustrate a multi-layer device having antipad extensions, in accordance with various embodiments;

FIGS. 9-10 illustrate a multi-layer device having antipad extensions, in accordance with various embodiments;

FIGS. 11A and 11B illustrate a multi-layer device having antipad extensions, in accordance with various embodiments;

FIG. 12 illustrates a process of developing antipad extensions in a multi-layer device, in accordance with various embodiments; and

FIG. 13 illustrates a method of constructing a multi-layer device, in accordance with various embodiments.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology is not limited to the specific details set forth herein and may be practiced using one or more implementations. In one or more instances, structures and components are shown in block diagram form in order to avoid obscuring the concepts of the subject technology. In other instances, well-known methods and structures may not be described in detail to avoid unnecessarily obscuring the description of the examples. Also, the examples may be used in combination with each other.

The present disclosure provides apparatuses and methods to achieve desired operation of an integrated circuit (IC), and specifically enables millimeter wave operations, incorporating antipad structures, shapes and formations within one or more layers of the IC. The IC may support any of a variety of devices, such as an Antenna in Package (AiP) based device, in accordance with various embodiments disclosed in this application.

The present disclosure provides structures based on flip chip Ball Grid Array (fcBGA or flip-chip BTA) technology designed at millimeter wave frequencies where there is no prior solution for ultra-wideband package designs as used in future communication systems, including 5G and beyond. These structures achieve the desired performance by implementation of irregular antipad shapes in the design, such as in an AiP, where they introduce resonances in the return loss of the structure and improve the operational bandwidth of the system. In determining the layers to implement these structures, the goal is to design the antipad so as to modify the electrical current distribution, which is achieved by modifying the equivalent capacitance corresponding to the antipad and according to the antipad shape and construction. The examples presented herein are provided for clarity of understanding and are not meant to be limiting; these examples optimize antipad shape, position and locations of voids to achieve wide band matching in the frequency of interest. The present disclosure is applicable to any conductive layer of the design and may take various shapes. The present disclosure provides a means to modify the current distribution to create wide band matching in any suitable ICs and AiP based devices.

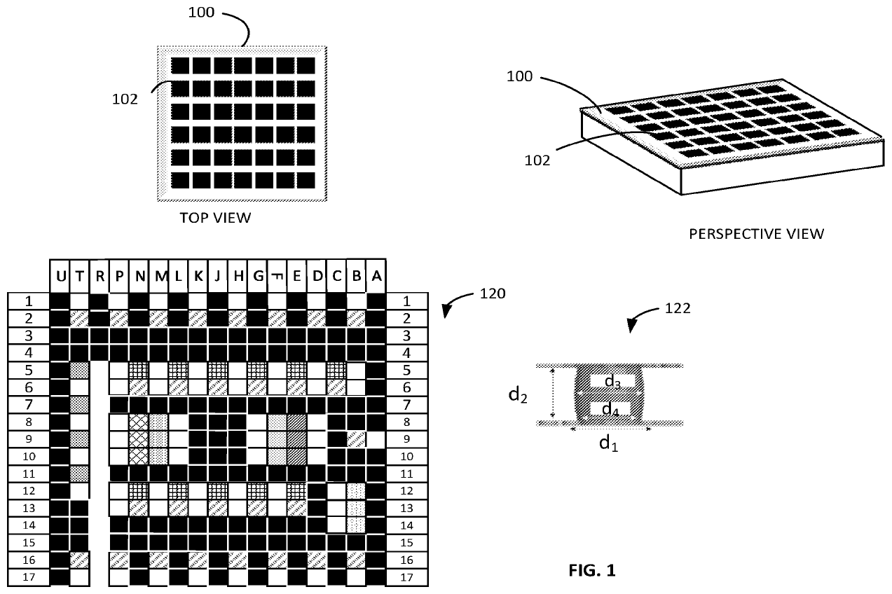

FIG. 1 illustrates an example configuration of an integrated circuity (IC) 100 having a plurality of elements 102 illustrated in a top view and a perspective view. The IC 100 is made up of multiple layers through which transmission lines or electrical conductors are configured. This configuration is referred to as a mapping and may be extremely complex as illustrated in a mapping 120 of a layer within the IC 100. Each block of the layer is defined by different parameters, such as material, conductor, open and so forth. The conductive portions are coupled between layers by connectors, such as connector 122. The connectors may be conductive materials, open vias, vias with conductive perimeter and so forth depending on the design. These mappings become very complex as the functionality and frequency of operation change.

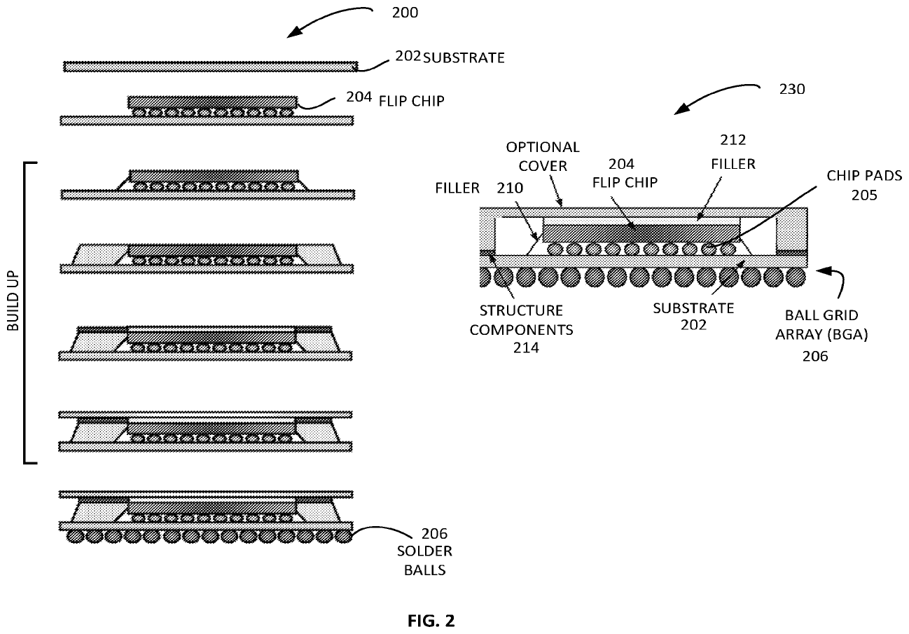

FIG. 2 illustrates a process 200 of building a Ball Grid Array (BGA) structure 230 by soldering or connecting directly between a chip carrier package and an interconnect substrate. These are also referred to as face-bonding or controlled collapse soldering. They may be configured in a variety of ways, such as peripheral arrays, staggered arrays, depopulated arrays or full area arrays. The BGA is similar to a flip chip device and is designed to increase the number and placement of input/output (I/O) connections as these connections are not limited to the periphery of the device. The BGA 230 is positioned on a substrate 202 with conductive structures or balls 205 coupled between a flip chip 204 and the substrate 202.

The build process starts with substrate 202 on which flip chip 204 is positioned, wherein the flip chip 204 includes chip pads 205 for electrical connection to couple with other components. Various structure components 214 are positioned to support the flip chip 204. Filler 212 is added on top of the flip chip 204 and then an optional cover 220 can be added. Finally, the BGA 206 is positioned on the opposite side of the substrate 202. The BGA structure or completed device 230 includes additional structures and fillers to complete the package, as illustrated in FIG. 2.

As discussed above with respect to FIGS. 1 and 2, BGA devices increase the lead count by using a larger area surface than the peripheral sides of the device. Additionally, in contrast to conventional chip designs, there are no leads to bend as the balls serve to make connections that are solid and not easily deformed. The devices further reduce coplanarity issues, handling issues and other problems associated with devices coupled on a board. During process, the solder balls are self-centering solving many of the placement issues of surface mount constructions. These configurations improve manufacturing yield and operational performance, including thermal and electrical characteristics. The design of a BGA device enables high density in miniature packages.

When used with a flip chip, e.g., fcBGA, the device enables interconnections between the flip chip die and the substrate. The BGA package may be assembled on multiple layers of metal on a high-density ceramic substrate or laminate. A variety of packaging may be used to provide access to the flip chip die or to protect the flip chip by encapsulation or other suitable construction. In FIG. 2, the device 230 encapsulates the flip chip 204 with fillers 210, 212 and an optional cover 220. The flip chip 204 includes chip pads 205 which are positioned proximate substrate 202, which is sandwiched between flip chip 204 and BGA 206. There are various structure components 214 to complete the package 230.

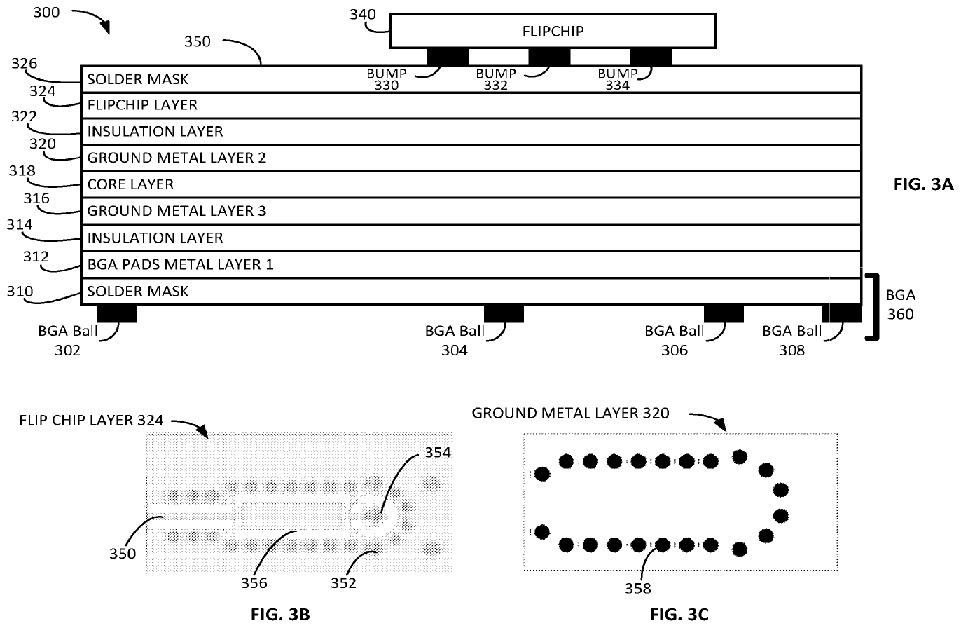

FIGS. 3A, 3B, and 3C illustrate a multi-layer device 300 incorporating antipad formations, in accordance with various embodiments. The multi-layer device 300 illustrated in FIG. 3A is an fcBGA device, which includes layers having a flip chip 340 with bumps 330, 332, 334, which are also referred to as chip pads 330, 332, 334, coupled to layer 326. The layers of the multi-layer device 300 include flip chip layer 324, BGA pads metal layer 312, ground (metal) layer 320, ground (metal) layer 316, dielectric (insulation) layer 314, dielectric (core) layer 318, dielectric (insulation) layer 322, and a solder mask or substrate layer 310. The BGA structures positioned under the substrate (e.g., the layers of the fcBGA device/multi-layer device 300) include BGA balls 302, 304, 306, 308. As illustrated in FIG. 3A, BGA 360 includes BGA pads (metal) layer 312 and BGA balls 302, 304, 306, 308.

Each layer of multi-layer device 300 is positioned and structured to facilitate circuitry and transmission paths supporting the flip chip 340 functionality and operation. These layers are connected through conductive paths, vias and other structures. Within a layer, there are conductive structures referred to as pads, that provide conductive connection between layers. A layer also includes open or non-conductive areas referred to as antipads.

The multi-layer device 300 is a structure having transition from flip chip to BGA balls in a multi-layer stack up, which in this case is four (4) layers. As illustrated in FIG. 3A, the flip chip 340 sits on the top layer 326 of the stack up. In the present disclosure, the transition from the chip pads 330, 332, 334 of the flip chip 340 to a flip chip layer 324 includes novel structures configured in the flip chip layer 340. The flip chip may have any number of chip pads according to the device design and purpose. Additionally, in the present disclosure, the transition from the flip chip layer to the BGA balls 302, 304, 306, 308, includes novel structures configured in the BGA pads layer 312. There are a variety of other stack ups that may be implemented and device 300 is provided as an example.

For the configuration of the multi-layer device 300 illustrated in FIGS. 3A, 3B, and 3C, the parameters of the layers, such as, for example, but not limited to dielectric permittivity, loss tangent, thickness and roughness of each of the layers, are determined as part of the design, configuration, operation, manufacturability, application, cost and so forth of the device. The BGA balls 302, 304, 306, 308 connect the multi-layer device 300 to a main board or other application structure. The core layer, such as layer 318, is sandwiched between metal layers 316 and 320. The solder mask layers 326 and 310 are positioned at opposite ends of the stack up. Filler is used between the solder mask layers 326 and flip chip 340, including in the areas of chip pads, such as an underfill material. There is open spacing between the BGA balls 302, 304, 306, 308. The BGA may have any of a variety of configurations, such as the ball mapping 120 of FIG. 1. In various embodiments, BGA balls may be of uniform size and shape. In various embodiments. BGA balls may be of nonuniform size and shape.

There are two transitions from the example of multi-layer device 300, with the signal transition from the flip chip 340 to the BGA balls 302, 304, 306, 308 and the routing is in the flip chip layer 324. The first transition matches the output of radio frequency (RF) channels from flip chip 340 to a microstrip line within the flip chip layer 324. A second part of the transition matches the microstrip line to BGA balls 302, 304, 306, 308.

The first transition, e.g., the flip chip transition, delivers the RF out signal of the flip chip 340 to a microstrip 350, as illustrated in FIG. 3A. The configuration of the stack up is designed to reduce unwanted reflections and increase transmission gain for a frequency range, which in this application is 78.5 GHz with 10 GHz of bandwidth.

In FIG. 3B, the various ports of the flip chip 340 are illustrated in layer 324 as gray circles 352. The transmission path illustrated in FIG. 3B, for example, includes a conductive pad 354 coupled to the microstrip 350 and a spacing 356 is provided around the combination of the conductive pad 354 and microstrip 350. FIG. 3C illustrates the various ports as circles 358 in (ground metal) layer 320.

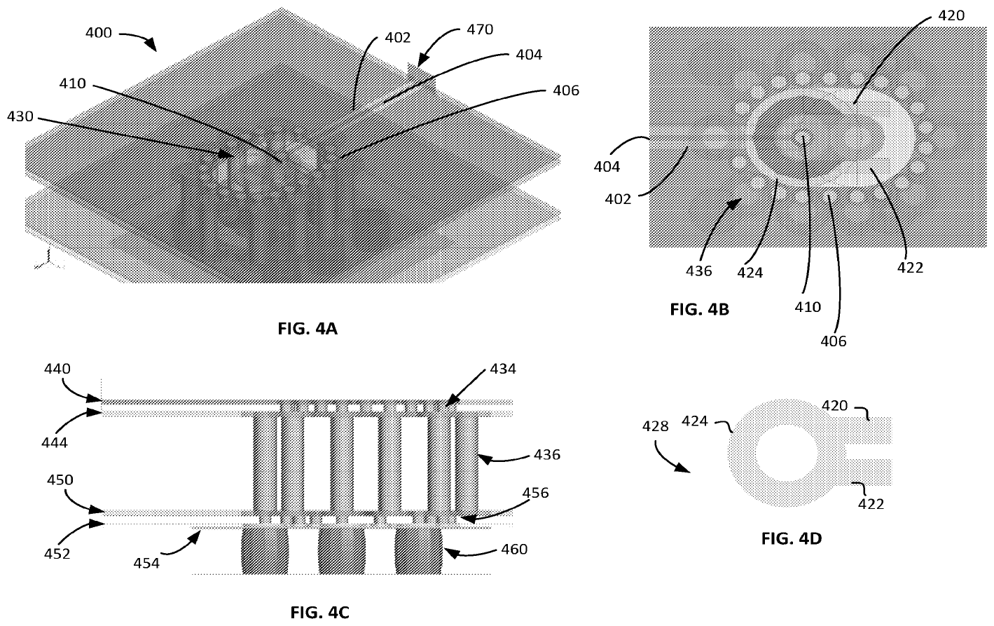

The second transition from the flip chip layer 324 to the BGA balls is designed to minimize reflection and insertion loss. This is further described below with respect to FIGS. 4A, 4B, 4C, and 4D.

FIGS. 4A, 4B, 4C, and 4D illustrate layers of an example multi-layer device in an example configuration 400 with antipad and conductive portions, in accordance with various embodiments. Specifically, FIGS. 4A, 4B, 4C, and 4D illustrate transition structures and ports within BGA pads layer 312, including a waveguide port 410 to drive a microstrip line 404 on the flip chip. The microstrip 404 is a path for transmission that is composed of a conductive material. As shown in FIG. 4A, the microstrip 404 is surrounded by spacing 402 to isolate the conductive transmission path provided by the microstrip 404. The spacing 402 is a stripline gap for the microstrip 404; this is an open area or discontinuity in the conductive layer. There are also conductive connections 406 to couple to the solder layer 310.

A top view of the BGA pads layer 312 is illustrated in FIG. 4B. The microstrip line 404 coupled to conductive pad 410 form a transmission path. Other conductive connectors 406 are positioned around the periphery of the transmission path. The connectors 406 are micro-stitching vias that connect layers with conductive material and may be hollow vias with conductive lining or other conductive structures. The connectors 406 are part of the complex circuitry and transmission paths of the Antenna in Package (AiP) layers.

In the example illustrated in FIG. 4D, an (irregularly shaped) antipad 428 includes a circular or donut shaped portion as well as two extension portions 422, 420. This shape is specific to the materials, shapes, sizes, frequency of operation and so forth of a given application. The antipad 428 is a transition structure composed of structures 420, 422, 424 which are spacings separating conductive portions of the layer 312, as illustrated in FIG. 4D. The structure 420, 422, 424 are also irregularly shaped antipads. The transition structure, i.e., antipad 428 has a main circular portion 424. There are transition extensions 420, 422 that are rectangularly shaped in the present example, but may take a variety of shapes. As the BGA pads layer 312 includes many connections to other layers of the stack up, which forms a complex configuration. The BGA pads layer 312 is densely filled with structures for such configuration. The transition extensions 420, 422 are positioned in footprint area of the layer that is available for building structures, as illustrated in FIGS. 4B and 4D. The radiating element 410 is composed of a conductive material and connects to microstrip line 404 which is a feed for the transmission signal. A second excitation port 430 is positioned proximate the radiating element 410 and is a cross section of a coaxial cable outer shell. Additional vias include a core layer hole through via 434 between layers, which in this example is a solid conductor. The layers illustrated in FIG. 4C include layer 440 and layer 444, each made of conductive material with vias therebetween.

Continuing with FIG. 4C, a conductive third metal layer 450 is positioned at an opposite end of vias 436. A fourth metal layer 452, the BGA pad layer, is proximate the third metal layer 450 having micro-stitching vias 456 therebetween. Another metal layer 454 is positioned proximate the BGA balls 460, as illustrated in FIG. 4C. A first excitation port 470 is positioned at the end of the transmission path and is a cross section a rectangular waveguide, as illustrated in FIG. 4A.

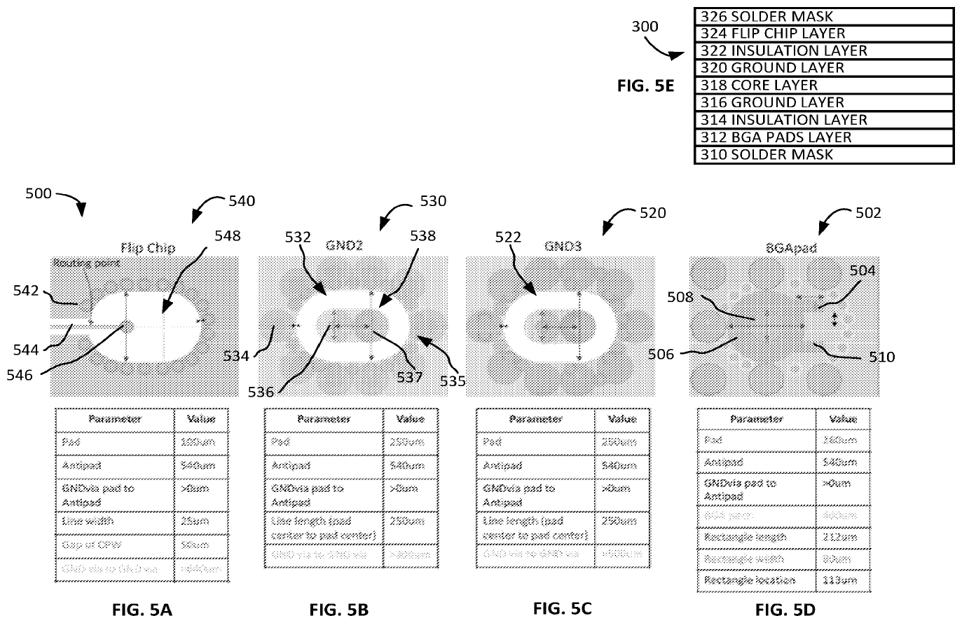

FIGS. 5A, 5B, 5C, 5D, and 5E illustrate individual layers of an example multi-layer device in an example configuration with specific antipad and conductive portions, in accordance with various embodiments. Specifically, FIGS. 5A, 5B, 5C, 5D illustrate several layers of an example fcBGA device 500 with the present disclosure at the top of a device near the flip chip, and FIG. 5E illustrates a schematic of the multi-layer device 300 of FIG. 3A as reference. As illustrated in FIG. 5A, the flip chip layer 540, corresponding to flipchip layer 324 of the multi-layer device 300 in FIG. 3A, has a conductive trace or transmission path 544, or routing path, ending in routing pad 546. An antipad 548 is an open space around the routing path 544; the open space is a discontinuity around the routing path 544. In this example, surrounding the antipad 548 are a series of conductive vias, such as via 542. Throughout the layers, various vias are implemented to conductively connect transmission paths and circuitry in different layers.

Continuing with FIG. 5B, a ground layer 530, corresponding to layer 320 of the multi-layer device 300 in FIG. 3A, is a metal layer with a discontinuity 532 (e.g., spacing) formed therein and having a shape corresponding to the perimeter of the antipad 548 with an internal conductive portion 538. The structure 538 includes a routing pad 536 aligned with routing pad 546 of layer 540 and another conductive pad 537, which is the pad of the core via 436 in FIG. 4C. In the multi-layer structure, conductive pads and vias are positioned to align and coordinate with components in other layers wherein the connection between the conductive pads and components form portions of transmission paths through the device. The BGA pad layer 530 includes conductive pad structures, such as pad 534, and vias, such as via 535.

Illustrated in FIG. 5C is a ground layer 520, corresponding to ground layer 316 of the multi-layer device 300 in FIG. 3A, is a metal layer with a discontinuity 522 similar to discontinuity 532 of layer 530 and other similar structures. FIG. 5D illustrates the bottom layer shown, which is BGA pads layer 502 having connection pads 508 to BGA balls (not shown) and a transition antipad structure 506 with transition extensions 504, 510. The main portion of the transition antipad structure 506 is a donut shaped discontinuity within a metal layer 502, similar to layer 312 of the multi-layer device 300 in FIG. 3A. As illustrated in FIGS. 5A, 5B, 5D, various parameters of the layers are provided in tables below the illustrations as follows, and including, for example, pad 534, pad 546, antipad 548, linewidth of routing path 544, structure 538, routing pad 536, routing pad 546, conductive pad 537, discontinuity 522, discontinuity 532, and various dimensions and parameters of features described with respect to fcBGA device 500, flip chip layer 540, ground layer 530, ground layer 520, and so on and so forth. The layout shapes and dimensions of the different features may take a variety of configurations.

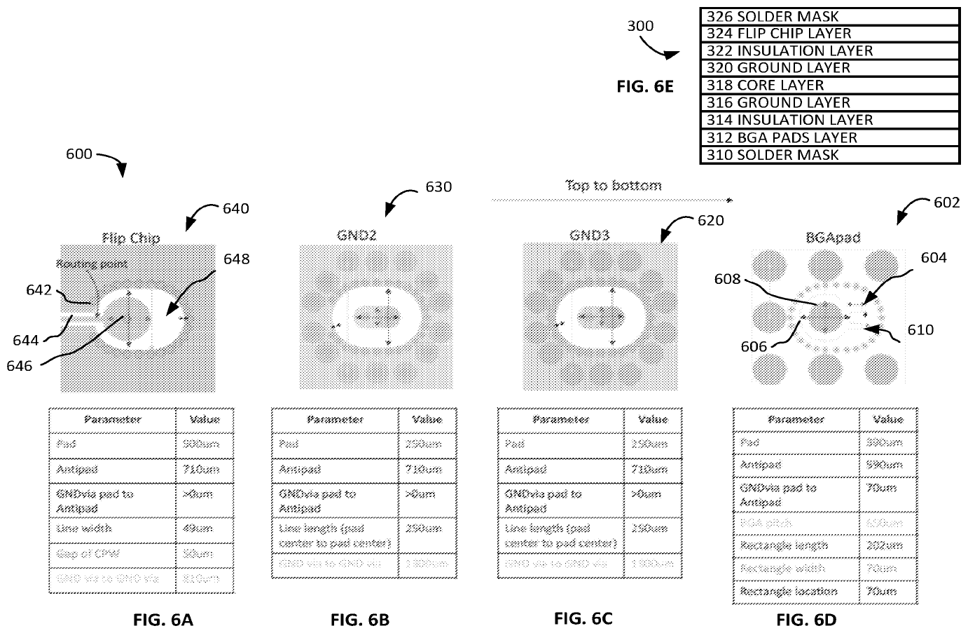

FIGS. 6A, 6B, 6C, 6D, and 6E illustrate individual layers of an example multi-layer device in an example configuration with specific antipad and conductive portions, in accordance with various embodiments. Specifically, FIGS. 5A, 5B, 5C, 5D illustrate several layers of an example device 600 in a transition design that is symmetric about a core layer similar to layer 318 of the multi-layer device 300 in FIG. 3A. FIG. 5E illustrates a schematic of the multi-layer device 300 of FIG. 3A as reference. The metal layers at a same distance from the core surface are approximately identical to the layers of the device 600 illustrated in FIGS. 6A, 6B, 6C, 6D, and 6E. The flip chip layer 640 is similar to layer 540 of FIG. 5A having routing path 644 with a larger pad area 646. Layers 630, 620 are similar to layer 530, 520 of FIGS. 5B and 5C. Layer 602 has similar to shape and alignment with layer 502 of FIG. however the size of the antipad 606 around pad 608 is smaller. The antipad structure 606 includes transition extensions 504, 510, which are each rectangular in shape. There are a variety of shapes and configurations possible for these transition structures.

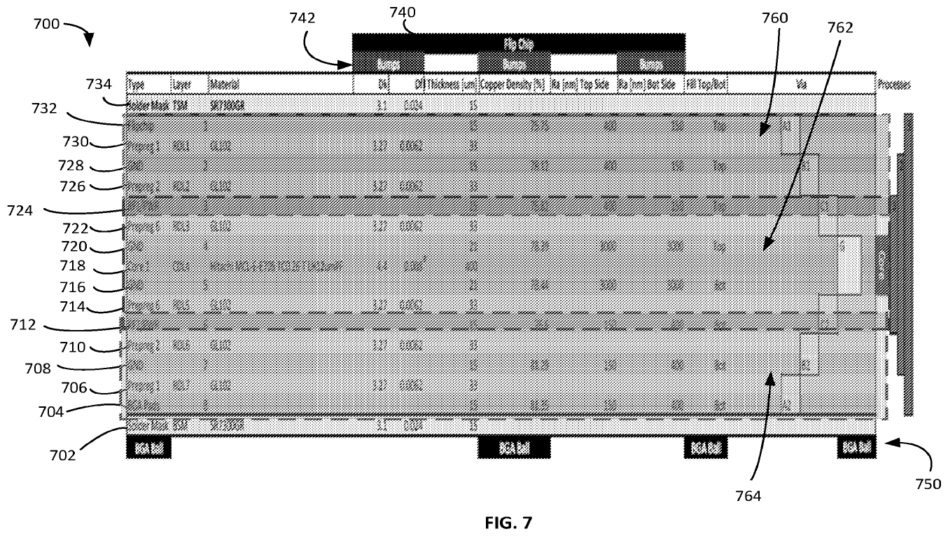

Now referring to FIG. 7, a multi-layer design, in one embodiment, is illustrated by layers 700 having a flip chip 740 positioned proximate a flip chip layer 732. At the opposite end of the layered structure is a BGA layer 704 proximate BGA balls 750. The basic structure of the layers 700 forming the device is similar to those of device 300, however additional layers and functionality are added. Additional layers enable the designer to use the opportunity presented by the extra layers to design the chip package and route the signal in less of package area and reduce the overall size of the package more conveniently. The layer stack from top to bottom includes a solder mask 734 proximate the flip chip and electrically connected to the flip chip pads, or bumps 742. A stack of layers is sandwiched between the flip chip layer 732 and an RF Power layer, RF1 724, and includes insulation layer 730, ground layer 728, and isolation layer 726. As in other examples presented herein the isolation layers may incorporate a prepreg or other material having the desired characteristics. A similar stack of layers is sandwiched between isolation layer 714 and the BGA layer 704, and includes RF power layer, RF2 712, isolation layer 710, ground layer 708, and isolation layer 706. Between the RF1 layer 724 and RF2 layer 712 is a stack of layers including isolation layer 722, ground layer 720, core layer 718, ground layer 716 and isolation layer 714. A solder mask layer 702 is positioned proximate the BGA layer 704 and the BGA bumps 750, wherein the solder layer 702 acts to electrically connect BGA layer 704 to BGA bumps 750. The layer structure of layer 700 is symmetric about the core layer 718. There are a variety of materials, dimensions and proportions that may be used to design and configured the layers 700. There may be more or less layers implemented as a function of the application, frequency range of operation, cost, size and other requirements.

As illustrated in FIG. 7, there are three transitions that are stacked on top of one another. A first transition is from flip chip 740 to RF1 layer 724, identified by block 760. A second transition is the transition from RF1 layer 724 to RF2 layer 712, identified by block 762. A third transition is the transition from RF2 layer 712 to BGA layer 704, identified by block 764. In this illustration, extra layers are incorporated to the structure of the multi-layer device 300 illustrated in FIG. 3A to enable additional routing of RF signals.

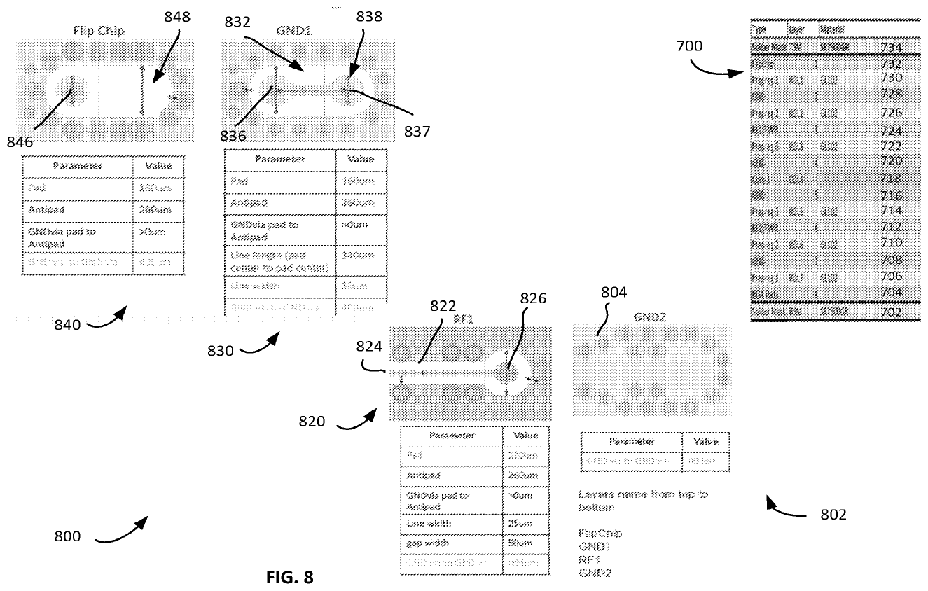

The first transition (block 760) from flip chip 740 to RF1 layer 724 is configured to deliver an RF signal from the flip chip 740 output to the RF1 layer 724 with reduced reflection and losses. Layout shapes are further illustrated in FIG. 8 for various layers. As shown in FIG. 8, flip chip layer 840, in one embodiment, includes conductive pad 846 is positioned within an antipad area 848. The conductive pad 846 is aligned with a chip pad of a flip chip. The shape of the antipad area 848 is an oval shape discontinuity within the flip chip layer 840, corresponding to layer 732 of FIG. 7. In ground layer 830, corresponding to layer 728 of FIG. 7, the antipad 832 has a shape similar to that of antipad 838; within the antipad 838, a conductive pad 836 is configured to couple with conductive pad 846 of layer 840 and a second conductive pad 837. The next layer 820 includes a conductive pad 826 aligned with pad 837 of layer 830. A routing line 824 connects to the pad 826 and an antipad structure surrounds the routing line 824 and the pad 826. The antipad 822 includes straight portions with the routing line 824 therebetween and a circular portion surrounding pad 826. A ground layer 802 has vias 804 positioned therein, as illustrated in FIG. 8.

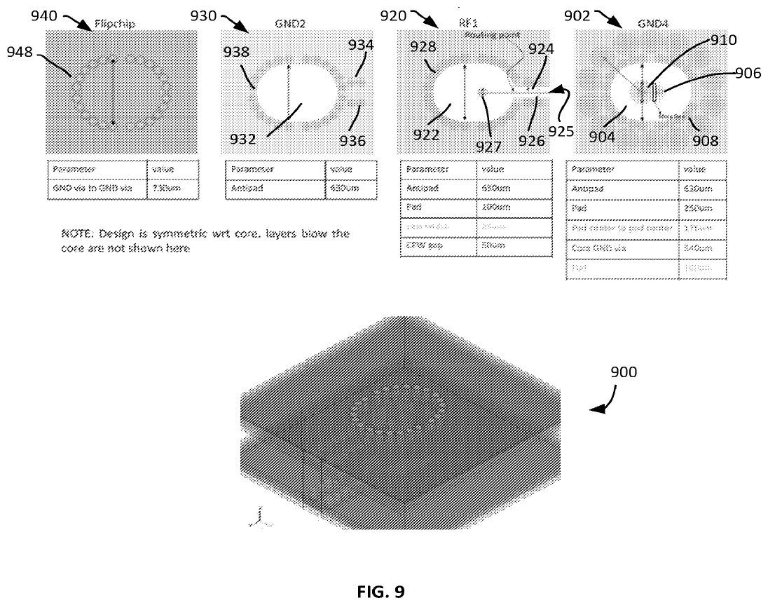

For the second transition from RF1 layer to RF2 layer, some layers are illustrated in FIG. 9 for a stack up 900, according to various embodiments. In a flip chip layer 940 are positioned a series of vias 948 arranged in a semicircular shape that corresponds to an antipad in other layers. In ground layer 930, vias 938 are similarly arranged in a semicircular shape with extension vias 934.936 projecting into an unused area of the layer 930 which are arranged around the microstrip line on 920. An antipad 932 is configured within and its shape defined by the vias 938. In RF1 layer 920, the semicircular shape is similarly used with the vias 928 defining an antipad 922. The pad 927 is positioned at the end of a routing line 925. The antipad 922 has extensions 924, 926 on each side of the routing line 925. In the next ground layer 902, an antipad 904 is positioned within vias 908. A pad 910 and a pad 906 are positioned within antipad 904. These structures deliver signals through different layers.

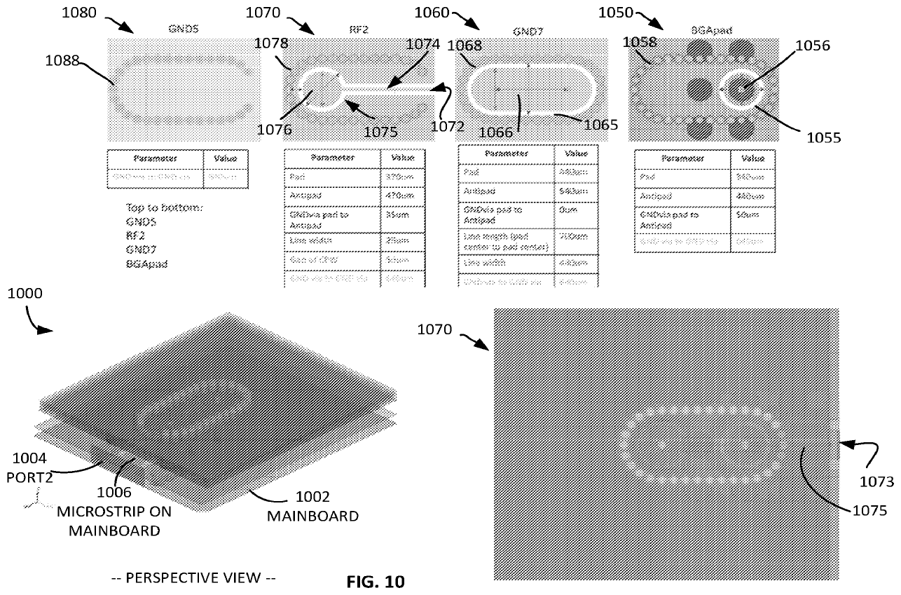

FIG. 10 illustrates the third transition to deliver the routed signal on RF2 Layer to the BGA balls, according to various embodiments. In this example, one end of this third transition is a 50 Ohm microstrip line 1072 on RF2 layer 1070 (wherein RF2 layer 1070 corresponds to layer 712 of layer stack up 700) and on the other end is a 50 Ohm microstrip line on a top layer of the reference mainboard 1002 which is excited using a waveguide port 1004. In this example, the transition is optimized to achieve a minimum reflection and maximum transmission around 78.5 GHz with 10 GHz of bandwidth at −10 dB return loss for this part of the transition scheme.

FIG. 10 illustrates this transition along with position of the ports and different layers of the package, according to various embodiments. In this transition, Port1 1073 is a rectangular waveport at the edge of the microstrip line 1072 on the RF2 layer 1070, and Port2 1004 is also a waveport (waveguide port) attached to a microstrip line 1006 on the mainboard 1002.

The ground layer 1080 includes an oval shape of vias 1088 positioned on a conductive material. The RF2 layer 1070 has a similar oval shape of vias 1078, within which is conductive pad 1076 coupled to a microstrip line 1072. The oval shape aligns with that of the other layers, 1080, 1060, 1050. The conductive pad 1076 and the micro strip line 1072 form a routing path 1074. The routing path 1074 is surrounded by antipad 1075. The ground layer 1060 includes an oval of vias 1068 within which is a pad area 1066 and antipad oval 1065.

The BGA layer 1050 includes an oval of vias 1058 within which is a pad 1056 surrounded by antipad 1055. The stack up 1000 is illustrated in perspective view with the mainboard 1002 on which the stack up 100 sits. The mainboard 1002 includes a port 1004 for driving the microstrip 1006.

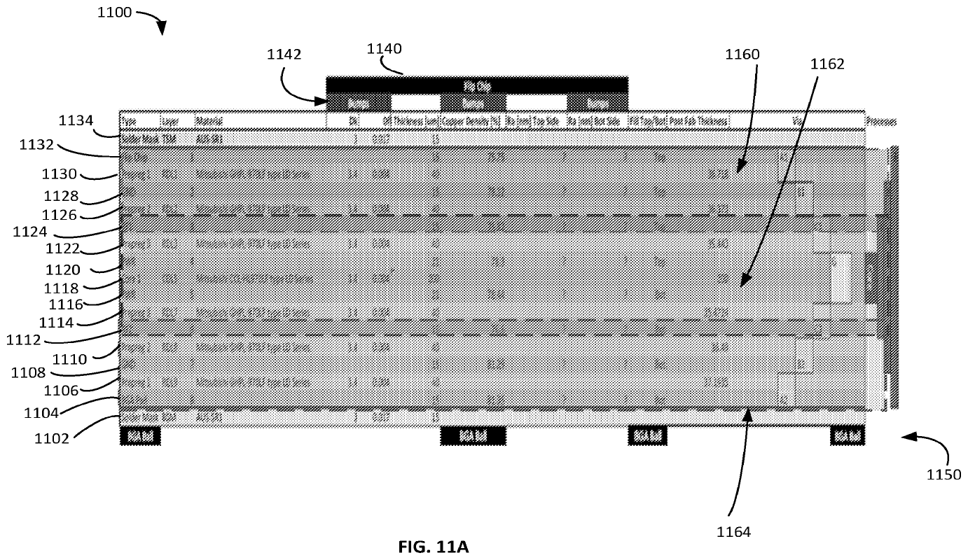

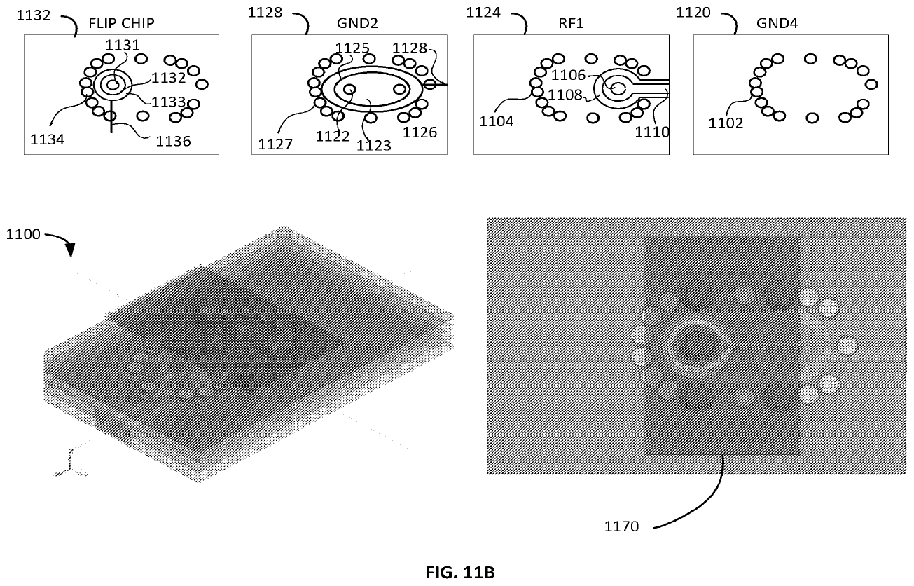

Another example stack up 1100 is illustrated in FIG. 11A. As shown in FIG. 11A, there are various layers including RF1 layer 1124, RF2 layer 1112, flip chip layer 1132 and BGA layer 1104. There are three transitions, indicated by boxes 1160, 1162 and 1164. The first transitions 1160 is from flip chip layer 1132 to RF1 layer 1124; a second transition 1162 is from RF1 layer 1124 to RF2 layer 1112; and a third transition is from RF2 layer 1112 to BGA layer 1104. As illustrated the flip chip 1140 and chip pads 1142 sit on top of stack up 1100. On the opposite end are the BGA balls 1150. In the center of stack up 1100 is a core layer 1118. The RF layers are provided for radio signals and/or digital signal processing. In this example, the core 1118 is a low loss dielectric layer with a thickness of approximately 200 um and is sandwiched between metal layers 1120 and 1116. The power and ground planes may be used interchangeably in these and other designs.

FIG. 11B illustrates some examples of the layers of stack up 1100, including flip chip layer 1132 having vias 1134 arranged therein. Flip chip placement is identified by rectangular area 1170 to sit on top of stack up 1100. The flip chip layer 1132 is positioned to electrically couple to at least one chip pad of the flip chip at position 1172.

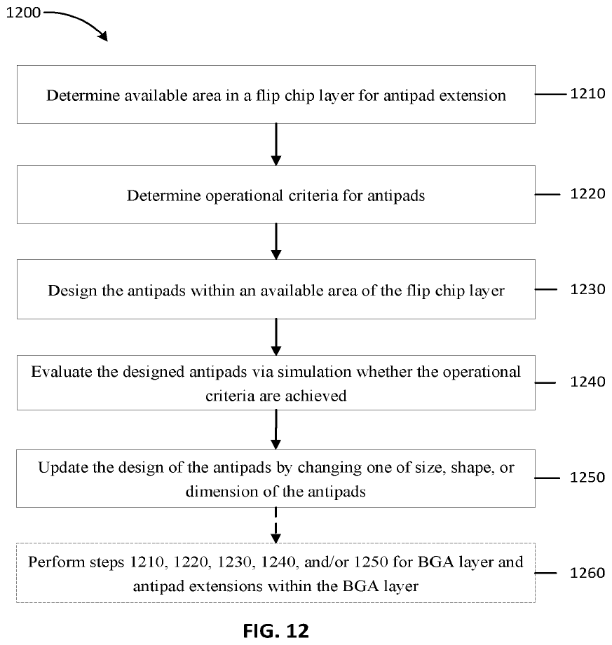

FIG. 12 illustrates a process 1200 for developing the antipad extensions in a multi-layer device, in accordance with various embodiments. The process 1200 includes determining available area in a flip chip layer for antipad extension, at step 1210. This is an area that is not used for conductive pads or other structures and that may be used to isolate the signals flowing through the device without interfering with operations thereof For each layer there are operational criteria for the antipads, such as loss level, reflection level and so forth, and thus the process 1200 includes determining operational criteria for the antipads, at step 1220. From this information the flip chip layer antipad extensions are designed within the available area, which culminates in the process 1200 with designing the antipads within an available area of the flip chip layer, at step 1230. The design is tested, such as by simulation, to achieve the operational criteria, which the process 1200 includes, at step 1240, as evaluating the designed antipads via simulation whether the operational criteria are achieved. If the design does not pass, the process updates design of the flip chip layer antipad extensions, which may involve sizing, shape change and so forth, and thus the process 1200 includes, at step 1250, updating the design of the antipads by changing one of size, shape, or dimension of the antipads. In various embodiments, a similar process 1260, which is similar to the process 1200, is applied to the BGA layer and antipad extensions formed therein. Accordingly, the process 1200 may further include, optionally, performing steps 1210, 1220, 1230, 1240, and/or 1250 for BGA layer and antipad extensions within the BGA layer, and/or any other suitable layers, such as ground layer, core layer, etc., as disclosed throughout the disclosure herein.

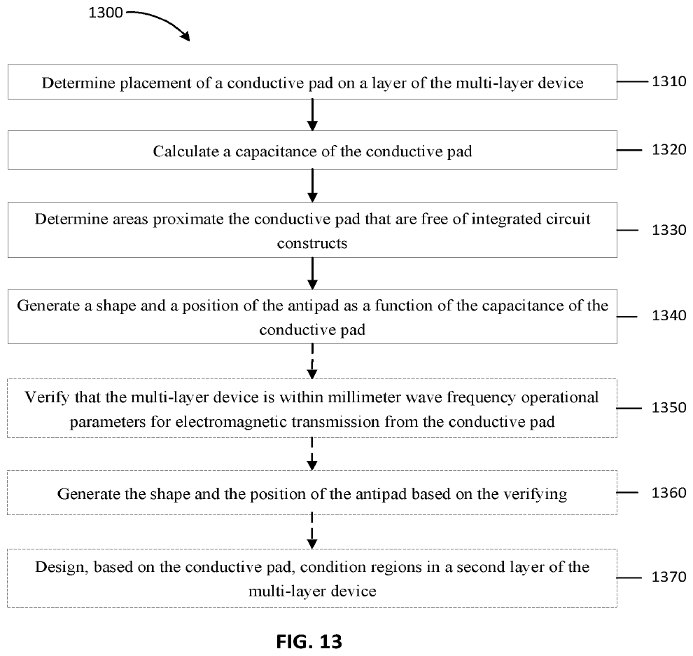

FIG. 13 illustrates a method 1300 of constructing a multi-layer device, in accordance with various embodiments. The method 1300 includes, at step 1310, determining placement of a conductive pad on a layer of the multi-layer device; at step 1320, calculating a capacitance of the conductive pad; at step 1330, determining areas proximate the conductive pad that are free of integrated circuit constructs, wherein the determined areas may comprise an antipad; and at step 1340, generating a shape and a position of the antipad as a function of the capacitance of the conductive pad. In various embodiments, the antipad is proximate the conductive pad and has antipad extensions away from the conductive pad.

In various embodiments and implementations, the method 1300 optionally includes, at step 1350, verifying that the multi-layer device is within millimeter wave frequency operational parameters for electromagnetic transmission from the conductive pad; and optionally includes, at step 1360, generating the shape and the position of the antipad based on the verifying.

In various embodiments and implementations, the layer of the multi-layer device is a first layer, and the method 1300 optionally includes, at step 1370, designing, based on the conductive pad, condition regions in a second layer of the multi-layer device. In some embodiments, the method 1300 can include designing the conductive regions in a second layer of the multi-layer device, wherein the conductive regions can be coordinated with or correspond to the conductive pad.

In accordance with various embodiments, a multi-layer electromagnetic device is provided. The device includes a first connectivity layer that includes a first conductive pad having a first capacitance, a feed line coupled between the first conductive pad and a transmit signal source, and a first antipad surrounding at least a portion of the first conductive pad for isolation of electromagnetic signals propagating through the first conductive pad. In various embodiments, the first antipad has a resonance that is a function of the first capacitance. The device also includes a second connectivity layer that includes a second conductive pad positioned for electrical connectivity to an external device and a plurality of layers positioned between the first connectivity layer and the second connectivity layer. In various embodiments, the first and/or second conductive pads can have antipad extensions into available area of the layer as a function of a capacitance of the conductive pads.

In accordance with various embodiments and implementations, a multi-layer electromagnetic device is described. The multi-layer electromagnetic device can include a first connectivity layer, including a first conductive pad that enables an electrical connectivity to a transmit signal source, where the first conductive pad has a first capacitance. The multi-layer electromagnetic device can also include a feed line coupled between the first conductive pad and the transmit signal source and a first antipad surrounding at least a portion of the first conductive pad that enables isolation of electromagnetic signals propagating through the first conductive pad. In various embodiments, the first antipad has a resonance that is a function of the first capacitance. Further, the multi-layer electromagnetic device can include a second connectivity layer having a second conductive pad that enables an electrical connectivity to an external device, and a plurality of layers positioned between the first connectivity layer and the second connectivity layer.

In accordance with various embodiments, the second connectivity layer can further include a second antipad surrounding at least a portion of the second conductive pad that enables an isolation of electromagnetic signals propagating through the second conductive pad. In various implementations, the first connectivity layer further includes a microstrip line coupled to the first conductive pad and an input port. In various embodiments, the first antipad surrounds at least a portion of the microstrip line. In various embodiments, the first antipad and the microstrip line form a routing path into the multi-layer electromagnetic device.

In various embodiments, the first antipad can include a first antipad structure proximate the first conductive pad, wherein the first antipad structure is a discontinuity in the first connectivity layer, and a second antipad structure coupled to the first antipad structure and extending into the first connectivity layer. In some embodiments, the first antipad structure has a first shape and the second antipad structure has a second shape different from the first shape. In various embodiments, the second antipad structure comprises two structures in parallel. In various embodiments, the first shape and the second shape are a function of the first capacitance. In various embodiments, the first connectivity layer, the second connectivity layer, and the plurality of layers form an antenna in package (AIP) device.

In accordance with various embodiments, the multi-layer electromagnetic device can include an integrated circuit mapping with the AIP device that is configured to operate in a millimeter wave frequency range of the electromagnetic signals. In various embodiments, the first antipad is a discontinuity within the first connectivity layer.

In accordance with various embodiments and implementations, a method of constructing a multi-layer device is described. The method includes determining placement of a conductive pad on a first layer of the multi-layer device; calculating a capacitance of the conductive pad; determining areas proximate the conductive pad that are free of integrated circuit constructs, wherein the determined areas comprise an antipad; and generating a shape and a position of the antipad as a function of the capacitance of the conductive pad, wherein the antipad is proximate the conductive pad and has antipad extensions away from the conductive pad.

In various embodiments, the method further includes verifying that the multi-layer device is within millimeter wave frequency operational parameters for electromagnetic transmission from the conductive pad; and generating the shape and the position of the antipad based on the verifying.

In various embodiments, the method further includes designing, based on the conductive pad, condition regions in a second layer of the multi-layer device.

In accordance with various embodiments and implementations, an antenna in package is described. The antenna in package includes a plurality of layers including a ground layer; an isolation layer; a first conductive layer comprising a first pad and a first antipad, wherein the first pad has a first capacitance is coupled to a signal transmission source and the first antipad has a resonance that is a function of the first capacitance of the first pad; and a second conductive layer comprising a second pad configured to provide electrical contact to an external device.

In various embodiments, the first antipad is a discontinuity within the first conductive layer and surrounds at least a portion of the first pad that enables an isolation of electromagnetic signals propagating through the first pad. In various embodiments, the first antipad includes a first antipad structure proximate the first pad, wherein the first antipad structure is a discontinuity in the first conductive layer. In various embodiments, the first antipad further includes a second antipad structure coupled to the first antipad structure and extends into the first conductive layer. In various embodiments, the first antipad structure has a first shape and the second antipad structure has a second shape different from the first shape.

In various embodiments and implementations as disclosed herein, the operational criteria include resonance characteristics and the capacitive, or reactance, value of the resonating element. This determines the shape of the antipad and the positioning with respect to the radiating elements. The design process is an iterative process in some examples, and in others the calculations are part of the electromagnetic signal simulations. The design is also constrained by requirements of the manufacturing process, including materials, dimensions, percentage of conductive material on a substrate or layer and so forth. These requirements may restrict the overall volume of the device, footprint, and/or cost.

It is appreciated that the previous description of the disclosed examples is provided to enable any person skilled in the art to make or use the present disclosure. Various modifications to these examples will be readily apparent to those skilled in the art, and the generic principles defined herein may be applied to other examples without departing from the spirit or scope of the disclosure. Thus, the present disclosure is not intended to be limited to the examples shown herein but is to be accorded the widest scope consistent with the principles and novel features disclosed herein.

As used herein, the phrase “at least one of” preceding a series of items, with the terms “and” or “or” to separate any of the items, modifies the list as a whole, rather than each member of the list (i.e., each item).The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

Furthermore, to the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate implementations can also be implemented in combination in a single implementation. Conversely, various features that are described in the context of a single implementation can also be implemented in multiple implementations separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. Moreover, the separation of various system components in the aspects described above should not be understood as requiring such separation in all aspects, and it should be understood that the described program components and systems can generally be integrated together in a single hardware product or packaged into multiple hardware products. Other variations are within the scope of the following claim.

What is claimed is:

1. A multi-layer electromagnetic device, comprising:
a first connectivity layer comprising:
a first conductive pad that enables an electrical connectivity to a transmit signal source, the first conductive pad having a first capacitance;
a feed line coupled between the first conductive pad and the transmit signal source; and
a first antipad surrounding at least a portion of the first conductive pad that enables isolation of electromagnetic signals propagating through the first conductive pad, wherein the first antipad has a resonance that is a function of the first capacitance;
a second connectivity layer comprising a second conductive pad that enables an electrical connectivity to an external device; and
a plurality of layers positioned between the first connectivity layer and the second connectivity layer.

2. The multi-layer electromagnetic device of claim 1, wherein the second connectivity layer further comprises a second antipad surrounding at least a portion of the second conductive pad that enables an isolation of electromagnetic signals propagating through the second conductive pad.

3. The multi-layer electromagnetic device of claim 1, wherein the first connectivity layer further comprises a microstrip line coupled to the first conductive pad and an input port.

4. The multi-layer electromagnetic device of claim 3, wherein the first antipad surrounds at least a portion of the microstrip line.

5. The multi-layer electromagnetic device of claim 4, wherein the first antipad and the microstrip line form a routing path into the multi-layer electromagnetic device.

6. The multi-layer electromagnetic device of claim 1, wherein the first antipad comprises:
a first antipad structure proximate the first conductive pad, wherein the first antipad structure is a discontinuity in the first connectivity layer; and
a second antipad structure coupled to the first antipad structure and extending into the first connectivity layer.

7. The multi-layer electromagnetic device of claim 6, wherein the first antipad structure has a first shape and the second antipad structure has a second shape different from the first shape.

8. The multi-layer electromagnetic device of claim 7, wherein the second antipad structure comprises two structures in parallel.

9. The multi-layer electromagnetic device of claim 7, wherein the first shape and the second shape are a function of the first capacitance.

10. The multi-layer electromagnetic device of claim 1, wherein the first connectivity layer, the second connectivity layer, and the plurality of layers form an antenna in package (AIP) device.

11. The multi-layer electromagnetic device of claim 10, further comprising:
an integrated circuit mapping with the AIP device that is configured to operate in a millimeter wave frequency range of the electromagnetic signals.

12. The multi-layer electromagnetic device of claim 1, wherein the first antipad is a discontinuity within the first connectivity layer.

13. A method of constructing a multi-layer device, comprising:
determining placement of a conductive pad on a layer of the multi-layer device;
calculating a capacitance of the conductive pad;
determining areas proximate the conductive pad that are free of integrated circuit constructs, wherein the determined areas comprise an antipad; and
generating a shape and a position of the antipad as a function of the capacitance of the conductive pad, wherein the antipad is proximate the conductive pad and has antipad extensions away from the conductive pad.

14. The method of claim 13, further comprising:
verifying that the multi-layer device is within millimeter wave frequency operational parameters for electromagnetic transmission from the conductive pad; and
generating the shape and the position of the antipad based on the verifying.

15. The method of claim 14, wherein the layer of the multi-layer device is a first layer, the method further comprising:
designing, based on the conductive pad, condition regions in a second layer of the multi-layer device.

16. An antenna in package, comprising:
a plurality of layers comprising:
a ground layer;
an isolation layer;
a first conductive layer comprising a first pad and a first antipad,
wherein the first pad has a first capacitance is coupled to a signal transmission source and the first antipad has a resonance that is a function of the first capacitance of the first pad; and
a second conductive layer comprising a second pad configured to provide electrical contact to an external device.

17. The antenna in package of claim 16, wherein the first antipad is a discontinuity within the first conductive layer and surrounds at least a portion of the first pad that enables an isolation of electromagnetic signals propagating through the first pad.

18. The antenna in package of claim 16, wherein the first antipad comprises a first antipad structure proximate the first pad, wherein the first antipad structure is a discontinuity in the first conductive layer.

19. The antenna in package of claim 18, wherein the first antipad further comprises a second antipad structure coupled to the first antipad structure and extends into the first conductive layer.

20. The antenna in package of claim 19, wherein the first antipad structure has a first shape and the second antipad structure has a second shape different from the first shape.
